(19) United States
(12) Patent Application Publication
(10) Pub. No.: US 2026/0016527 A1
(43) Pub. Date: Jan. 15, 2026

(54) SYSTEMS AND METHODS OF POWER ELECTRONIC ANALYSIS AND CONTROL

(71) Applicant: UCHICAGO ARGONNE, LLC, Chicago, IL (US)

(72) Inventors: Moinuddin AHMED, Darien, IL (US); Zhenghong TU, Bolingbrook, IL (US); Christopher STANKUS, Chicago, IL (US)

(73) Assignee: UCHICAGO ARGONNE, LLC, Chicago, IL (US)

(21) Appl. No.: 19/208,464

(22) Filed: May 14, 2025

Related U.S. Application Data
(60) Provisional application No. 63/671,578, filed on Jul. 15, 2024.

(51) Int. Cl. G01R 31/26

(52) U.S. Cl. CPC G01R 31/2642; G01R 31/2628

(57) ABSTRACT

A method for simulating failure testing of in-situ power grid hardware in real-time can include extracting, by one or more processors, parameters from power grid dynamics data to perform power grid simulation testing, sending, by the one or more processors, a reference to a power grid device, generating, by the one or more processors, stress information based on the reference via the power grid device to a power grid hardware, collecting, by the one or more processors, a response from the power grid hardware to the stress information, identifying, by the one or more processors, behaviors of the response, and extracting, by the one or more processors, a failure and aging model of the power grid hardware.

### CROSS-REFERENCE TO RELATED APPLICATION

The present application claims priority to U.S. Provisional Patent Application No. 63/671,578, filed on Jul. 15, 2024, the disclosure of which is incorporated herein by reference in its entirety and for all purposes.

### STATEMENT OF GOVERNMENT INTEREST

This invention was made with government support under Contract No. DE-AC02-06CH11357 awarded by the United States Department of Energy. The government has certain rights in the invention.

### FIELD OF DISCLOSURE

The present disclosure relates generally to power grid hardware. Specifically, the current disclosure relates to systems and methods of power electronic analysis and control.

### SUMMARY

At least one implementation of the present disclosure relates to a method. The method includes extracting, by one or more processors, parameters from power grid dynamics data to perform power grid simulation testing, sending, by the one or more processors, a reference to a power grid device based on the parameters, generating, by the one or more processors, stress information based on the reference sent via the power grid device to a power grid hardware, collecting, by the one or more processors, a response from the power grid hardware to the stress information, identifying, by the one or more processors, behaviors of the response, and extracting, by the one or more processors, a failure and aging model of the power grid hardware.

In various implementations, the stress information includes voltage, current, and temperature signals. The power grid hardware can be a wide bandgap power electronic. The power grid device can be a power amplifier. The response can include drain-source voltage (Vds), gate-source voltage (Vgs), gate-source current (Igs), and drain-source current (Ids) data.

In various implementations, collecting the response further includes collecting the response over a plurality of time points for the response. The power grid dynamics data can be at least one of historic power grid dynamics data or real-time power grid dynamics data. The reference can include voltage, current, and temperature parameters.

Another implementation relates to a system including one or more processors. The one or more processors to extract parameters from power grid dynamics data, send a reference, based on the parameters, to a power grid device, generate stress information based on the reference via the power grid device to a power grid hardware, collect a response from the power grid hardware to the stress information, identify behaviors of the response, and extract a failure and aging model of the power grid hardware.

In various implementations, the stress information comprises voltage, current, and temperature signals. The power grid hardware can be a wide bandgap power electronic. The power grid device can be a power amplifier. The response includes drain-source voltage (Vds), gate-source voltage (Vgs), gate-source current (Igs), and drain-source current (Ids) data.

In various implementations, collecting the response further includes collecting the response over a plurality of time points for the response. The power grid dynamics data can be at least one of historic power grid dynamics data or real-time power grid dynamics data. The reference can include voltage, current, and temperature parameters.

Another implementation relates to a method. The method can include applying, by one or more processors, at least one operating voltage on a power electronic comprising at least one electrical device. The method can include determining, by the one or more processors, at least one electronic power loss of the power electronic corresponding to the at least one operating voltage based on at least one device power loss of the at least one electrical device. The method can include determining, by the one or more processors, at least one electronic temperature of the power electronic based on at least one device temperature of the at least one electrical device and the at least one device power loss. The method can include determining, by the one or more processors, at least one device operating life span of the at least one electrical device based on the at least one device temperature. The method can include determining, by the one or more processors, based on the at least one device operating life span, an electronic operating life span of the power electronic.

In various implementations, the at one electrical device includes a capacitor and a metal-oxide-semiconductor field-effect transistor (MOSFET) and the power electronic includes an inverter, the at least one operating voltage corresponding to power grid dynamics. The at least one device power loss can be determined using parameters determined by electrical simulations, the parameters including at least one of current, voltage, resistive power loss, and switching power loss.

In various implementations, the method can include receiving, by the one or more processors, parameters of the power electronic indicating an output of the power electronic. The method can include determining, by the one or more processors, a power electronic age based on the parameters. The method can include in response to determining that the power electronic age is greater than or equal to a first threshold and less than or equal to a second threshold, adjusting an output of the power electronic. The method can include in response to determining that the power electronic age is greater than the second threshold, generating a notification to an operator. The first threshold and the second threshold can be determined based on the electronic operating life span.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are, therefore, not to be considered limiting of its scope, the disclosure will be described with additional specificity and detail through use of the accompanying drawings.

FIG. 1 is a block diagram of an example system for performing real-time failure analysis simulations on in-situ power grid hardware, according to some implementations.

FIG. 2 is a block diagram of an example process for performing real-time failure analysis simulations on in-situ power grid hardware, according to some implementations.

FIG. 3 is a block diagram of an example system for performing real-time failure analysis simulations on in-situ power grid hardware, according to some implementations.

FIG. 4 is a flow diagram of a method for performing real-time failure analysis simulations on in-situ power grid hardware, according to some implementations.

FIG. 5 is a graph of an example response of the power grid hardware.

FIG. 6 is a graph of an example response of the power grid hardware where failure occurs.

FIG. 7 are graphs of responses of the power grid hardware pre-stress information generation, post-stress information generation, and post-re-stress information generation.

FIG. 8 is a block diagram of an example system for performing thermal analysis on power grid hardware, according to some implementations.

FIG. 9 is a flow diagram of an example process for determining a operating life span of power grid hardware, according to some implementations.

FIG. 10 is a schematic of an example simulated power grid hardware, according to some implementations.

FIG. 11 is a schematic of example thermal analysis on the simulated power grid hardware of FIG. 10, according to some implementations.

FIG. 12 is a chart of predicted power grid hardware operating life span based on the thermal analysis of FIG. 11.

FIG. 13 is an example control system for an example power grid hardware, according to some implementations.

FIG. 14 is an example graph of an output of the power grid hardware of FIG. 13 using the control system of FIG. 13, according to some implementations.

FIG. 15 is a flow diagram of an example method for determining an electronic operating life span and generating a failure and aging model, according to some implementations.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION OF VARIOUS IMPLEMENTATIONS

Before turning to the figures, which illustrate certain exemplary implementations in detail, it should be understood that the present disclosure is not limited to the details of methodology set forth in the description or illustrated in the figures. It should also be understood that the terminology used herein is for the purpose of description only and should not be regarded as limiting.

Following below are more detailed descriptions of various concepts related to, and implementations of methods and systems for power electronic analysis and control. The various concepts introduced above and discussed in greater detail below may be implemented in any of numerous ways as the described concepts are not limited to any particular manner of implementations. Examples of specific implementations and applications are provided primarily for illustrative purposes.

Wide bandgap power electronics are used in a variety of industries such as energy generation, distribution, and transmission as well as electric vehicle infrastructure and renewable energy integration. Wide bandgap power electronics are a class of semiconductor devices with wider bandgaps compared with traditional silicon-based semiconductors such as gallium nitride (GaN). The wide bandgap allows devices to have increased efficiency, higher operating temperatures, higher power density, etc. compared to silicon-based semiconductors. In the power grid context, the wide bandgap power electronics can be implemented in solid-state transformers, grid-tied inverters, converters, energy storage systems, etc. to reduce energy waste, increase voltages, etc. Prior to implementing the wide bandgap power electronics into power grids, failure analysis can be performed to determine a lifespan of the device and failure conditions (e.g., upper threshold of voltage) using, for example, a failure and aging model.

Power grid dynamics can include variations in parameters such as, but not limited to, fluctuation in energy demand such as having higher demands in winter versus the summer. Other variations can include, but are not limited to, output adjustments to match real-time demand, voltage adjustments, temperature, humidity, sudden loss of power generation, short circuits, and the like. Variations in power grid dynamics can affect the lifespan and failure conditions of the device, such as an inverter.

While the systems and methods of the present disclosure are directed towards failure testing and life span analysis of wide bandgap power electronics using, for example, a simulation integrated with a physical power grid, it is to be understood that the methods described herein can be implemented or integrated within any system that may perform any combination of sending reference information, collecting stress information, identifying stress information behaviors, and extracting a failure and aging model of the wide bandgap power electronics. The methods described herein can be implemented or integrated within any system that may perform any combination of determining power loss and temperature to determine operating life spans Furthermore, the systems and methods as described further herein may apply to at least one of a device, a power electronic, components of a power grid, or any electrical device on.

Failure analysis of wide bandgap power electronics in power grids typically use stress tests to identify how the device (e.g., wide bandgap power electronic, etc.) handles various stress factors such as high voltage, high current, temperature fluctuations, and transient events (e.g., thunderstorms, etc.). Various parameters are assessed during the stress tests such as electrical performance, thermal performance, failure modes, and device lifetime estimation. The parameters are monitored to assess the reliability and operational limits of the power electronics device.

Conventional techniques to perform failure analysis of wide bandgap power electronics may rely on testing without considering the dynamics of power grids (e.g., voltage fluctuations, etc.). Such conventional techniques lack real-time insights into the dynamic behavior of various components of the power grid during operation, creating challenges in pinpointing root causes of failure. Other conventional techniques utilize ex-situ stress tests to evaluate power electronic device responses to predetermined variations in voltage, current, and temperature. However, these tests neglect the impact of real-time power grid dynamics and the stresses that occur. Typically, failure models extracted from ex-situ stress tests have weak adaptivity to varying operating conditions in the power grids. The evaluation of the power grid device can thus degrade significantly from within the lab to installed on the power grid.

Systems and methods as described herein enable incorporation of real-time impact of power grid dynamics in the failure analysis of power electronics. By integrating a real-time simulation platform with grid dynamics, the simulation platform can perform stress testing on individual devices (e.g., wide bandgap power electronic devices, etc.) and incorporate the complexities and variations inherent in real-world power grid operations. The simulation platform can be an in-situ grid dynamics real-time tool to dynamically provide references to the individual devices for stress information generation. The references can include, for example, voltage, current, temperature, etc. The simulation platform can determine power loss and temperature of the devices in response to the grid dynamics, and estimate an operating life span of the device based on at least the temperature. Systems and methods as described herein replicate real-world operations environment of power electronics converters with specific topology through the real-time digital simulation of the power grid. The experimentation performed can provide more realistic data for extraction of failure and aging models of individual power electronic devices.

### Power Electronic Failure Analysis

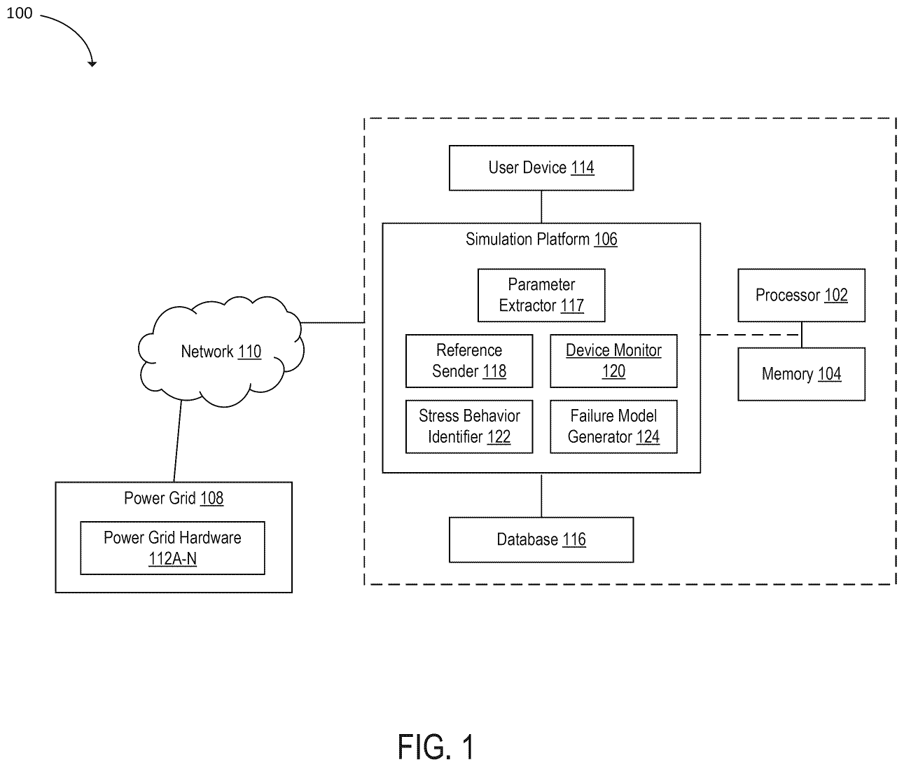

FIG. 1 depicts an example system 100 for a performing in-situ (e.g., real-world, in real time, etc.) power electronics failure analysis. The system 100 can include one or more processors 102 and memory 104, which can be implemented as one or more processing circuits. The processor 102 may be a general purpose or specific purpose processor, an application specific integrated circuit (ASIC), one or more field programmable gate arrays (FPGAs), a group of processing components, or other suitable processing components. The processor 102 may be configured to execute computer code or instructions stored in memory 104 (e.g., fuzzy logic, etc.) or received from other computer readable media (e.g., CDROM, network storage, a remote server, etc.) to perform one or more of the processes described herein. The memory 104 may include one or more data storage devices (e.g., memory units, memory devices, computer-readable storage media, etc.) configured to store data, computer code, executable instructions, or other forms of computer-readable information. The memory 104 may include random access memory (RAM), read-only memory (ROM), hard drive storage, temporary storage, non-volatile memory, flash memory, optical memory, or any other suitable memory for storing software objects and/or computer instructions. The memory 104 may include database components, object code components, script components, or any other type of information structure for supporting the various activities and information structures described in the present disclosure. The memory 104 may be communicably connected to the processor 102 and may include computer code for executing (e.g., by processor 102) one or more of the processes described herein. The memory 104 can include various modules (e.g., circuits, engines) for completing processes described herein. The one or more processors 102 and memory 104 may include various distributed components that may be communicatively coupled by wired or wireless connections; for example, various portions of system 100 may be implemented using one or more client devices remote from one or more server devices. The system 100 can include any one or more rules, heuristics, logic, code, functions, machine learning models, neural networks, algorithms, or various combinations thereof to implement one or more components of the system 100.

The system 100 can include a simulation platform 106. The simulation platform 106 can be used to perform failure analysis on in-situ power electronics. To do so, the simulation platform 106 can be communicatively coupled to a power grid 108 via a network 110. The power grid 108 can be a testing site for the power grid hardware 112A-N (herein referred to the power grid hardware 112). For example, the power grid 108 can replicate a real-world operation environment of a power electronics converter by including a hardware loop which can include the power grid hardware 112 including a power amplifier, wide bandgap power converter and/or device, analog-to-digital (A/D) converters, and digital-to-analog (D/A) converters. The simulation platform 106 can run various devices within the hardware loop under varying grid topologies and parameters to check failures of the power grid hardware 112. The power grid hardware 112 can also include inverters, converters, energy storage components (e.g., batteries), electric vehicle charging stations, solar panels, etc. with various topologies. Grid topology can refer to different configurations of the power grid 108 (e.g., different devices, electrical connections, etc.). The power grid hardware 112 can include wide bandgap power electronics.

The simulation platform 106 can be coupled to a user device 114 to provide input into the simulation platform 106 as well as a database 116 to store information of previous simulation runs, historic data of the power grid hardware 112, etc. The parameters of the simulation platform 106 can be based on historic power grid data stored in the database 116. The user can communicate with the simulation platform 106 via the user device 114 to initiate a simulation as well as adjust parameters of the simulation. For example, the user can choose which of a plurality of the power grid hardware 112 to perform failure analysis on. In various implementations, the simulation platform 106 is directly coupled to the power grid 108 and the network 110 is not included. In various implementations, the simulation platform 106 includes the processor 102 and the memory 104.

The simulation platform 106 can include one or more parameter extractors 117. The parameter extractor 117 can translate historic power grid data into streams of data (e.g., voltage, current, etc.) to determine the grid topology and parameters. The parameter extractor 117 can extract parameters of historic and real-time (e.g., live) power grid dynamics data and convert the parameters for implementation within the power grid 108. To extract the parameters from the data, the parameter extractor 117 can parse and process the historic and real-time power grid dynamics data to extract the streams of data. The real-time power grid dynamics data can be received via the network 110. The parameter extractor 117 can extract parameters per scenario. For example, the parameter extractor 117 can extract parameters from a single day stored in the historic power grid dynamics data to run a simulation. In various implementations, the parameter extractor 117 extracts based off of user input and/or extracts based on a desired failure test.

In various implementations, the parameter extractor 117 is a machine learning model that receives power grid dynamics data as an input, and outputs various parameters such as voltage, current, temperature, pressure, etc. based on the power grid dynamics data. The parameter extractor 117 can be trained on historic power grid dynamics data to output parameters, and then fed live power grid dynamics data.

The simulation platform 106 can include one or more reference senders 118. The reference sender 118 can send a reference (e.g., signal) to the power grid hardware 112 based on parameters extracted by the parameter extractor 117. The reference can vary across individual devices of the power grid 108 (e.g., the power grid hardware 112) based on grid topology and variations of input and output parameters. For example, different devices of the power grid 108 may react differently to the parameters of the reference. The reference can include parameters such as voltage, temperature, current, pressure radiation etc. to simulate real-world operating conditions and guide stress information generation by, for example, a power amplifier included in the power grid hardware 112. For example, the reference can indicate to introduce electromagnetic noise into the power grid hardware 112 to test a resilience of the power grid hardware 112 against electromagnetic interference (EMI). The stress information can be generated by various components (e.g., a power amplifier) of the power grid 108.

In various implementations, the reference sender 118 can dynamically send references to the power grid 108 based on real-time (e.g., live) or historic power dynamics of a real-world power grid. The references can include load shedding, frequency control, voltage regulation, and other dynamics that exist within the real-world power grid. Other references the reference sender 118 can send, but is not limited to, include overvoltage (e.g., applying voltages higher than a nominal operating voltage), overcurrent, EMI, electromagnetic compatibility (EMC), voltage transients, temperature cycling, and thermal shock.

The reference can include one or more parameters extracted by the parameter extractor 117. For example, in response to the parameter extractor 117 extracting voltage parameters from the power grid dynamics data, the reference sender 118 can send the voltage parameters to the power grid 108 to test the power grid hardware 112 via the reference.

In various implementations, the reference sender 118 can send one or more references. For example, to emulate the power grid dynamics data, the parameter extractor 117 can extract one or more sets of parameters for the reference sender 118 to generate references off of. In this case, different references can be sent to different devices of the power grid 108. The reference sender 118 can also adjust, based on user input, the references based on which device of the power grid hardware 112 to focus testing on (e.g., a wideband gap power electronic, etc.). For example, the references can be tailored to test a failure and lifespan of the wideband gap power electronic.

In various implementations, the power grid 108 is a real-world power grid, and the reference sender 118 sends references to a device (e.g., power amplifier, etc.) coupled to the power grid hardware 112 based on dynamics of the real-world power grid. In this case, the simulation platform 106 is communicatively coupled to the power grid 108. In various implementations, the power grid 108 is a testing environment (e.g., the hardware loop, etc.) in which the power grid hardware 112 is coupled to. In this case, the reference sender 118 can send references based on real-world power grid situations stored in the database 116. For example, the database 116 can include a plurality of historic dynamics of real-world power grids, and the reference sender 118 can send references based on the plurality of historic dynamics. The user can select which of the plurality of dynamics to test the power grid hardware 112 with via input through the user device 114 to the simulation platform 106. The database 116 can also include references based on failure analysis standards (e.g., IEC 61000, etc.) of the power grid hardware 112.

Once the reference is sent by the reference sender 118, one or more of the power grid hardware 112 can response to the stress information generated by the device (e.g., power amplifier) which can be recorded by the device monitor 120. The device monitor 120 can monitor, for example, drain-source current (Ids), gate leakage current (Igs), gate-source voltage (Vgs), and drain-source voltage (Vds) to determine power grid hardware 112 failure and behavior. Ids is the current flowing between a drain and source terminal of the power grid hardware 112. Igs is the current that flows through a gate terminal of the power grid hardware 112. Vgs is a voltage difference between the gate and source terminal of the power grid hardware 112. Vds is a voltage difference between the drain and source terminals of the power grid hardware 112.

In various implementations, the device monitor 120 can record and store data (e.g., Ids) of the power grid hardware 112 into the database 116. The device monitor 120 can also store associations of which reference resulted in the response of the power grid hardware 112. In various implementations, the device monitor 120 can output a graph and update the graph in real-time based on the reference and the response of the power grid hardware 112. For example, as the power grid hardware 112 is responding to the reference, the device monitor 120 can dynamically update a graph to reflect the parameters of the power grid hardware 112. In various implementations, the device monitor 120 is an analog-to-digital (A/D) converter and converts the stress information of the device into a digital format.

The simulation platform 106 can include one or more stress behavior identifiers 122. The stress behavior identifier 122 can receive information from the device monitor 120 and identify the behavior (e.g., trends) of the power grid hardware 112 in response to the reference. For example, over multiple simulations, the stress behavior identifier 122 can parse through the stress information stored in the database 116 and identify potential faults and failure modes of the power grid hardware 112. The stress behavior identifier 122 can identify that the power grid hardware 112 fails, for example, during overvoltage references. The stress behavior identifier 122 can process the Ids, Igs, Vgs, and Vds of the power grid hardware 112 and determine if any changes or failure occurs due to the reference. For example, peaks in the Igs can indicate failure of the power grid hardware 112. The stress behavior identifier 122 can use a machine learning model to parse through the signals and identify stress behaviors.

In various implementations, the stress behavior identifier 122 inputs the graph provided by the device monitor 120, and identifies points of failure of the power grid hardware 112. The stress behavior identifier 122 can output behavior analysis of the power grid hardware 112 to the user device 114. In various implementations, the stress behavior identifier 122 can pinpoint and recommend which part of the power grid hardware 112 is causing failure. In various implementations, the stress behavior identifier 122 can identify failure of the power grid hardware 112 while the power grid hardware 112 is generating stress information in response to the reference (e.g., in real-time).

The simulation platform 106 can include one or more failure model generators 124. The failure model generator 124 can be used to identify failure modes and an operational lifespan of the power grid hardware 112. Based on analysis of the stress behavior identifier 122, the failure model generator 124 can identify common failure modes (e.g., failure during surges) as well as a predicted operational lifespan of the power grid hardware 112. For example, based on a plurality of references sent to the power grid hardware 112, the failure model generator 124 can determine the operational lifespan of the power grid hardware 112 in the real world based on, for example, statistics of the reference occurring. The failure model generator 124 can extract a failure and aging model of the power grid hardware 112 from data provided by the stress behavior identifier 122. The failure model generator 124 can then output the failure and aging model to the user device 114. The failure and aging model can be used to predict an operating life of the power grid hardware 112, and can be used to determine maintenance periods and replacement of the power grid hardware 112. The failures and aging model can also be used to adjust or change the power grid hardware 112, such as modifying configurations or materials to length the operating life.

In some implementations, the failure model generator 124 can take data extracted from conventional reliability testing of the power grid hardware 112 (e.g., not with the simulation platform 106, etc.), and generate failure and aging models.

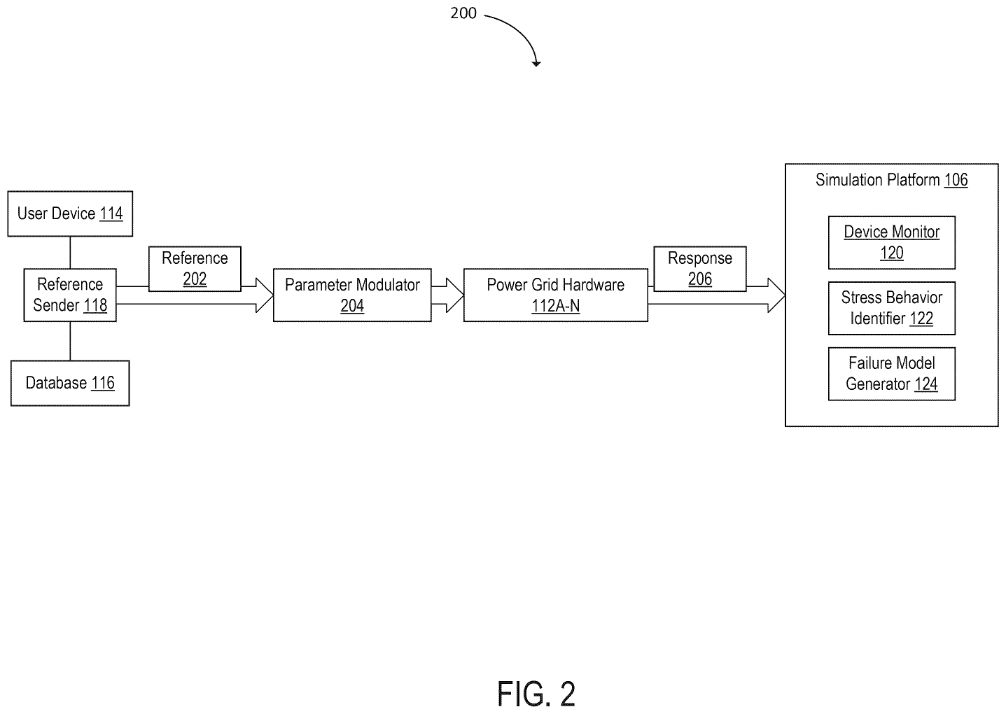

FIG. 2 is a block diagram of a process 200 for performing real-time failure analysis simulations on in-situ power grid hardware, according to some implementations. The process 200 can be implemented by, for example, the system 100 and/or any other system.

The reference sender 118 can generate and send a reference 202. The reference 202 can be in a digital format, and include instructions to guide stress information generation. Depending on failure analysis tests being run, the reference 202 can be based on real-life situations (e.g., rainstorms) and include parameters such as, but not limited to, temperature, voltage, current, humidity, etc. In various implementations, the reference 202 can be input and output through a D/A converter.

In various implementations, the reference 202 can be selected from a plurality of references 202 stored in the database 116. For example, the user can select a reference 202 to be sent via the user device 114. The user can also, for example, program the reference sender 118 to continuously send one or more references 202 over a time period. In various implementations, the reference sender 118 sends one or more references 202 over the time period to mimic dynamics of a power grid. The user can input the time period and adjust a frequency of the references 202 sent by the reference sender 118.

The reference 202 can be received by a parameter modulator 204. The parameter modulator 204 can include, but not limited to, a power amplifier, a multimeter, and/or any other device capable of adjusting voltage, current, temperature, and/or humidity. Depending on the reference 202, the parameter modulator 204 can select parameters and sweeps (e.g., a range of a parameter to be changed in a time period) to input into the power grid hardware 112. For example, the parameter modulator 204 can input voltage in a range of 1V to 5V in a 2 minute period. The parameter modulator 204 generates stress information based on the guidance of the reference 202.

Once the power grid hardware 112 receives the stress information from the parameter modulator 204, the power grid hardware 112 can generate a response 206. The response 206 can be measured in Igs, Ids, Vgs, and Vds. The response 206 can indicate power outages of the power grid hardware 112 as well as failure based on the reference 202 sent by the parameter modulator 204. The response 206 can be monitored by the device monitor 120. The device monitor 120 can include a display to display the Igs, Ids, Vgs, and Vds on graphs.

The device monitor 120 can track changes in the Igs, Ids, Vgs, and Vds of the power grid hardware 112 to determine failure and power outages. For example, peaks in the Igs can indicate over current and power grid hardware 112 failure. In various implementations, the device monitor 120 sends an indication to the user device 114 to notify the user of failure in the power grid hardware 112. In this case, the device monitor 120 can also send an indication to the reference sender 118 and/or the simulation platform 106 to stop sending references 202 if the reference sender 118 is sending one or more references 202.

In various implementations, the device monitor 120 monitors the power grid hardware 112 in real-time. For example, as the power grid hardware 112 is generating the response 206 in response to the reference 202, the device monitor 120 records the response 206 as the Vgs, Ids, Igs, and Vds fluctuates over the time period of the generated stress information.

The stress behavior identifier 122 can receive the output (e.g., data, graphs) of the device monitor 120 and determine how the power grid hardware 112 behaves under various stress information. For example, the stress behavior identifier 122 can compare the reference 202 with a corresponding output of the device monitor 120 to identify stress behavior and/or failure modes of the power grid hardware 112. Stress behaviors can include, for example, the Vgs of the power grid hardware 112 decreasing in response to a reference 202 decreasing the temperature.

Following completion of the reference sender 118 sending references 202, the failure model generator 124 can receive the data collected by the device monitor 120 and create a failure and aging model of the power grid hardware 112. The failure and aging model can be based on parameters of the generated stress information, and fluctuations of the Vgs, Ids, Igs, and Vds of the power grid hardware 112. The failure and aging model can thus represent an operational lifespan and failure of the power grid hardware 112.

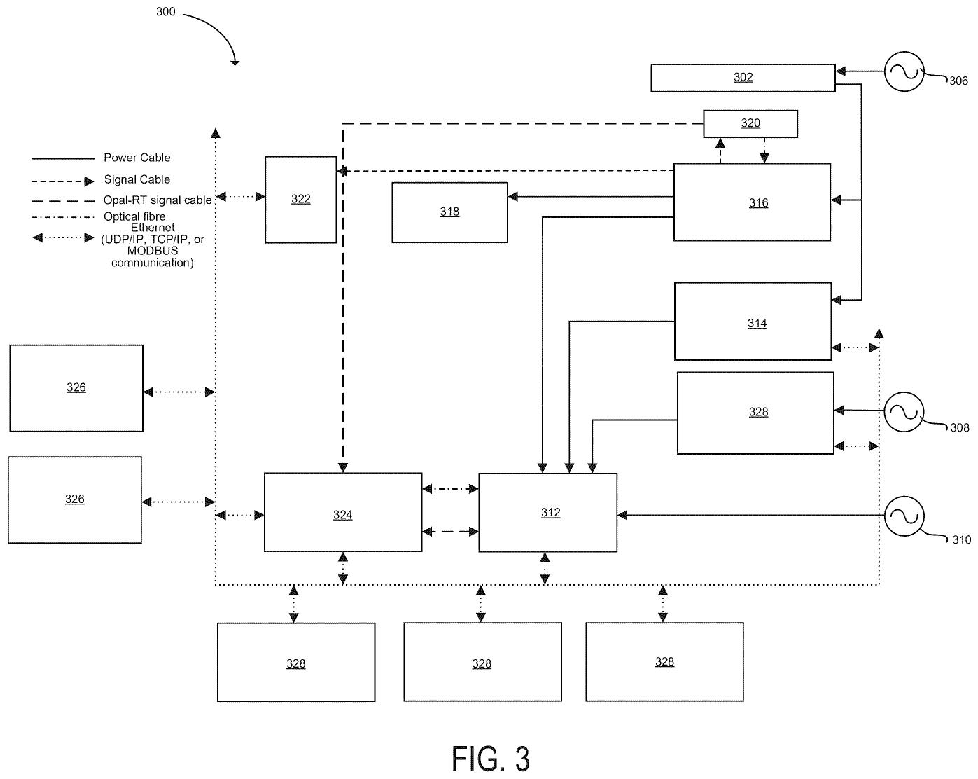

FIG. 3 is a block diagram of an example system for performing real-time failure analysis simulations on in-situ power grid hardware, according to some implementations. In this case, the system 300 includes one or more computing systems, one or more edge devices, one or more test instruments, one or more converters, one or more inverters, one or more power supplies, one or more cables, one or more simulators, and one or more references.

To simulate power grid dynamics, references can be sent to a first power supply 302 and a second power supply 304. The first power supply 302 can be a programmable DC power supply with 0-300 volts direct current (VDC), 5.4 A, and 1.54 kilowatt (KW). The second power supply 304 can be a BK Precision programmable 1-ph (single-phase power) AC power supply with 0-300V, 12 A, 1.5 kilo-volt-amperes (kVA). Example references that can be sent to the power supplies 302, 304 can include a first reference 306 with 1 ph, 120V, and 15 A, and a second reference 308 with 1 ph and 208/240 V. A third reference 310 with 3 ph and 4810V can be sent to a first simulator 312. The first simulator 312 can be an Opal-RT OPI420-20 PHIL with 120 volts alternating current (VAC), 400 Vdc, and +10 kW. The first power supply 302 and the second power supply 304 can be coupled to the first simulator 312 via power cables and send direct current or alternating currents. For example, the first power supply 302 can be coupled to an inverter 314 (e.g., Fronius 1-phase Solar Inverter with 208V, 15.8 A, and 3.8 kW) and send the first reference 306 via direct current through a power cable. The inverter 314 can then convert the direct current to alternating current and send the first reference 306 via alternating current to the first simulator 312.

The first power supply 302 can be coupled to a converter 316 (e.g., Imperix SiC half-bridge converter rack) which can be coupled to the first simulator 312. The converter 316 can receive the first reference 306 from the first power supply 302, convert the direct current to alternating current or the direct current to another direct current. The converter 316, following conversion, sends the first reference 306 to the first simulator 312. The converter 316 can also be coupled to a DC load 318 (e.g., Programmable DC Electronic Load with 0-120V, 240 A, and 1500 W). The DC load 318 can consume DC electrical power to control an electrical load of the system 300. The converter 316 can send direct current to the DC load 318.

The converter 316 can also be coupled to an interface 320 (e.g., Imperix interface board) to switch signals (e.g., DC to AC or DC to DC), and to provide current and voltage measurements to the interface 320 via a signal cable. The converter 316 can also be coupled to a test instrument 322 (e.g., oscilloscope) via a signal cable to measure signals (e.g. voltage signals).

The second power supply 304 can send the second reference 308 via alternating current to the first simulator 312. The third reference 310 can be directly sent to the simulator 312 without conversion, inversion, or through a power supply.

In turn, the first simulator 312 can be coupled to a second simulator 324 (e.g., Opal-RT OP5707XG Simulator with 3.3 gigahertz (Ghz) and 16 cores) via an optical fiber and an Opal-RT signal cable. The first simulator 312 can receive the signals (e.g., stress signals, conversion of references), while the second simulator 324 manages transmission and/or distribution of the references to one or more computers 326 and one or more edge devices 328. In this case, the second simulator 324 also converts the signals via pulse width modulation (PWM) received from the first simulator 312 to deliver to the computers 326 and the edge devices 328.

In some implementations, the first simulator 312 and the second simulator 324 can be stress behavior identifiers (e.g., the stress behavior identifier 122). The first simulator 312 and the second simulator 324 can receive stress signal information and identify trends and failure modes. The first simulator 312 and the second simulator 324 can identify stress behaviors from a system level (e.g., the system 300), to the device level (e.g., components of the system 300). The inverter 314 and the converter 316 can identify stress signals across the system 300 which can then be translated to a device level stress signal via simulation program with integrated circuit emphasis (SPICE) simulation. For example, the inverter 314 and the converter 316 can receive the system 300 level stress information, and identify which device of the system 300 is producing the stress signal via SPICE simulation.

The computers 326 can monitor the system 300 and provide an interface for user input. For example, the user can adjust the first reference 306 and monitor signals via the test instrument 322. The computers 326 can be coupled to various components of the system 300 via an ethernet cable (e.g., UDP/IP, TCP/IP, or MODBUS communication).

The edge devices 328 can provide control, optimization, and cybersecurity algorithms to the system 300. For example, the edge devices 328 can adjust parameters of the first reference 306 to better simulate the real-world power grid dynamics. The edge devices 328 can also emulate software for grid devices to more accurately reflect real-world power dynamics. Examples of the edge devices 328 include the NVIDIA Jetson AGX Orin 64 GB, NVIDIA Jetson Orin Nano, and a Raspberry P13. The edge devices 328 can be coupled to various components of the system 300 via an ethernet cable. Both the edge devices 328 and the computer 326 can control, adjust, and monitor all components of the system 300 (e.g., inverter 314).

The system 300 can simulate real-world power grid dynamics to failure and stress test various components of the system 300. A power grid electronic, such as a wideband gap power electronic, can also be coupled to the system 300 to failure and stress test the power grid electronic and/or various components of the system 300.

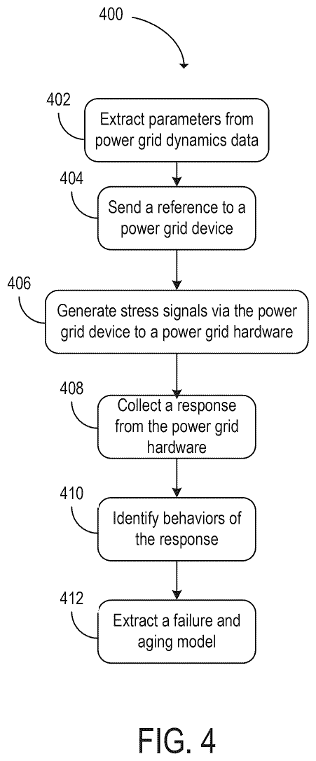

FIG. 4 is a flow diagram of a method 400 for performing real-time failure analysis simulations on in-situ power grid hardware, according to some implementations. The method 400 can be performed using various systems described herein. Various steps in the method 400 may be repeated, omitted, performed in various orders, or otherwise modified. Various steps in the method 400 may be run concurrently, in parallel, or individually.

At 402, parameters are extracted from power grid dynamics data to be used by a simulation. For example, parameters such as voltage, current, temperature, etc. are extracted from the power grid dynamics data for input into the power grid hardware.

At 404, a reference is sent. The reference can be sent to, for example, a power grid device which can be a power amplifier, a multimeter, and/or any other device capable of adjusting various parameters (e.g., voltage, current, temperature). The reference can include the extracted parameters to test the power grid hardware on.

At 406, the power grid device generates stress information to a power grid hardware. The power grid hardware can include power electronics such as a wide bandgap power electronic. The stress information can include modulating the various parameters. For example, the stress information can include inputting a current of 5 A into the power grid hardware and ramping up the current to 20 A at a rate of 1 A/minute.

At 408, a response is collected from the power grid hardware. The Ids, Igs, Vgs, and Vds of the power grid hardware can change based on the stress information. The response can include data on the Ids, Igs, Vgs, and Vds of the power grid hardware.

At 410, behaviors of the response can be identified. For example, peaks in the Ids can be identified and can indicate failure of the power grid hardware. Variations of voltage, current, and temperature can also be identified at 408. In this case, variations in voltage, current, and temperature can signify system level load and environment variation (e.g., seasons, locations, day/night).

At 412, a failure and aging model is extracted. Based on the response and behaviors of the response, the operational lifespan and failure modes of the power grid hardware can be identified. The failure and aging model can be used to determine service periods of the power grid hardware.

### Performance Evaluation

To measure the Ids of the power grid hardware, a custom test software was used with a Keithley 2461 Sourcemeter was used at a Vds bias with a max current 7 A at 5V and 5 A at 10V. To measure the Igs of the power grid hardware, a Keithley 6482 Picoammeter was used at a Vgs bias with a max current of 22 mA. A power amplifier was also used as part of a grid simulation. To reflect different dynamic operations of power grids, different Vgs values and sweeping mechanisms were used. Ramp and gate switch test series included 0 Vds and 0-5 Vgs, 5 Vds and 0-5 Vgs, 10 Vds and 0-5 Vgs, and 10 Vds and 0-10 Vgs where the test series was stopped early if failure was observed. Ramp tests occurred with 3 minute linear ramps of Vgs with static Vds while gate switch tests switched between low and high Vgs points. An additional ramp test was performed to determine post-stress performance with an exponential 10 second sweep of 15 Vds and 0-10 Vgs and 20 Vds and 0-10 Vgs. Pre-stress 0-5 Vgs sweep, 5 Vds and 1 Vds were performed. Post-stress 0-5 Vgs sweeps, 1 Vds were also performed. Failure was indicated when no switching behavior was observed and was confirmed by a post-stress sweep.

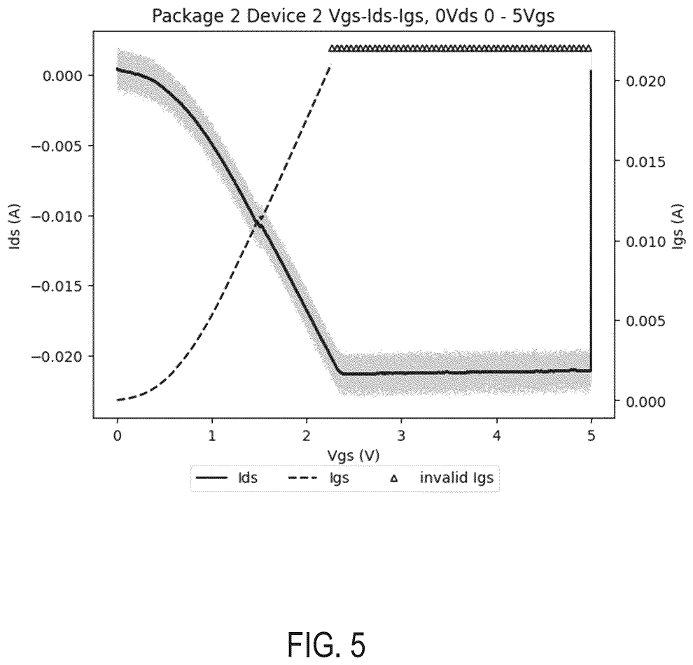

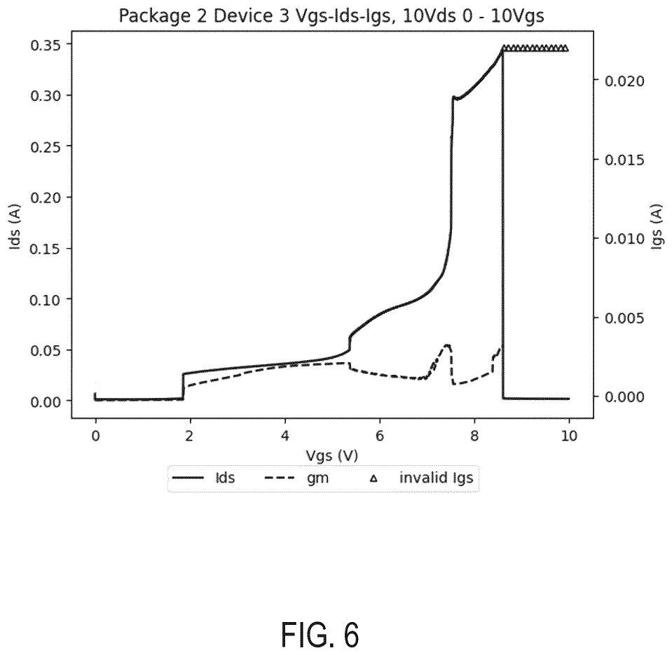

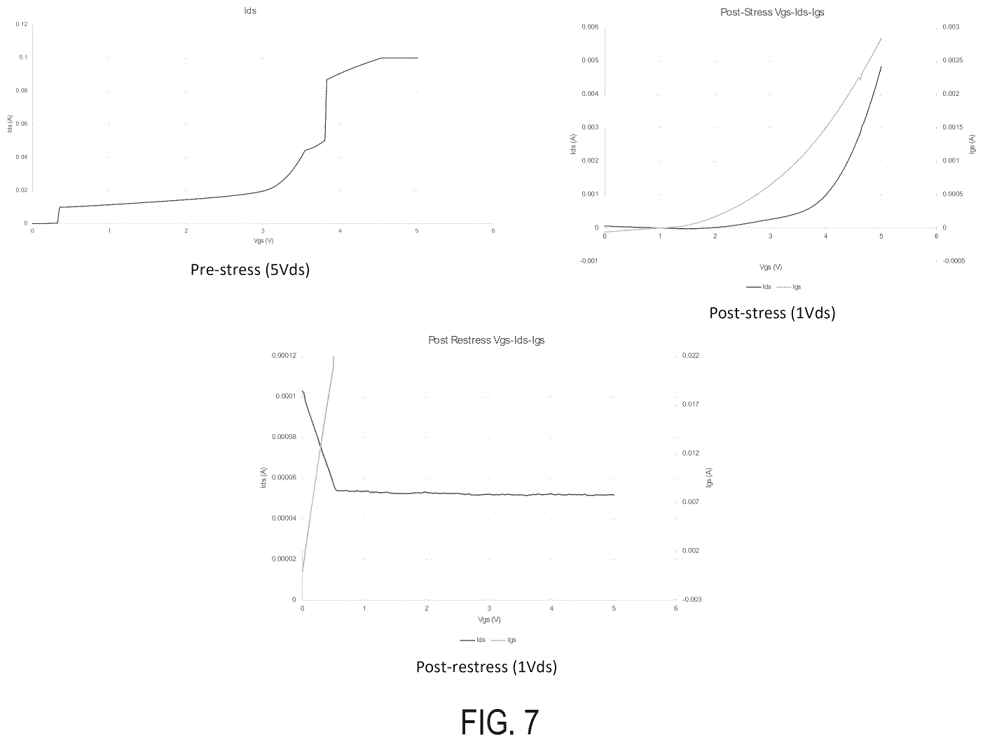

FIG. 5 is a graph of an example response of the power grid hardware. The graph shows a device that underwent 0 Vds and a sweep of 0-5 Vgs showing both valid and invalid Igs measurements. FIG. 6 is a graph of an example response of the power grid hardware where failure occurs. In this case, failure occurred during a 10 Vds and 0-10 Vgs sweep test where failure was indicated by a peak and sudden drop of the Igs. FIG. 7 are graphs of responses of the power grid hardware pre-stress information generation, post-stress information generation, and post-re-stress information generation.

### Power Electronic Thermal Analysis

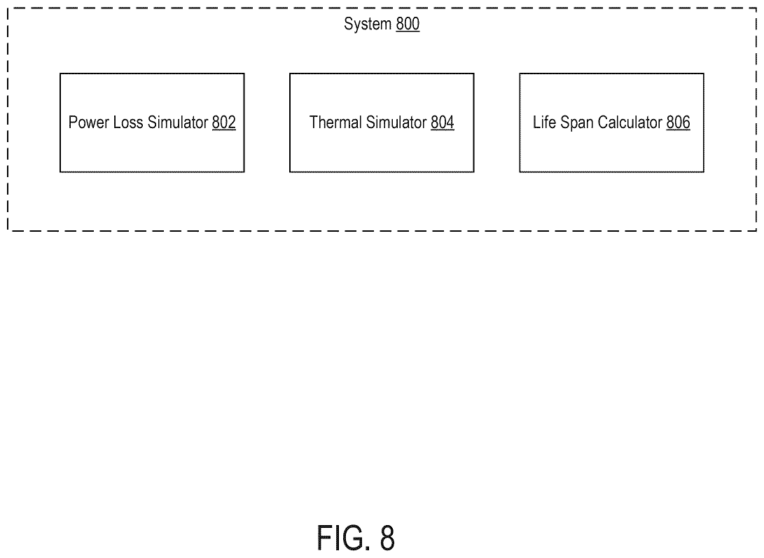

FIG. 8 shows an example system 800 for determining an operating life span of the power grid hardware using thermal analysis. The system 800 can be electrically coupled to the converter 316. For example, the system 800 can receive the direct current from the converter 316, and determine the operating life span based on at least the direct current.

The system 800 can include at least one power loss simulator 802. The power loss simulator 802 can generate a simulation of an example power grid hardware, such as an inverter, and determine the power loss of the inverter based on an operating condition of the inverter. For example, the power loss simulator 802 can generate an inverter including material properties of the inverter. For example, the power loss simulator 802 can generate an inverter with a specified geometry, material composition (e.g., percent silicon, etc.), etc. The power loss simulator 802 can generate the inverter with airflow properties, such as a cooling type (e.g., liquid cooling, forced-air cooling, etc.), airflow direction, ventilation, etc. The power loss simulator 802 can generate the inverter according to a datasheet including dimensions and specifications of the inverter. For example, the power loss simulator 802 can store a number of technical data sheets to generate simulated power grid hardware, and can adjust at least the material and airflow properties.

Following generation of the inverter, the power loss simulator 802 can determine a power dissipation across the inverter given different operating conditions, such as a percent of rated voltage of the inverter (e.g., nominal output voltage of the inverter, etc.). The operating condition can include at least 50, 100, a maximum rated voltage, and 110 percent of rated voltage of the inverter. For example, the voltage of operation of the inverter can be in a range between 200 to 1100 V, such as 400, 800, 850, and 880. The operating condition of the inverter can correlate to the power grid dynamics. For example, the converter 316 can provide the direct current which can determine the operating condition of the inverter.

The power loss simulator 802 can include the SPICE simulation to determine one or more electrical properties of the inverter based on the operating condition. The power loss simulator 802 can input the material and airflow properties of the inverter and the operating condition to the SPICE simulation to determine at least a current flowing through the inverter. The power loss simulator 802, based on the operating conditions and the electrical properties, can determine at least the resistive and switching power loss of the inverter. For example, the power loss simulator 802 can determine the resistance of the inverter from the material properties and the determined current to determine the resistive power loss of the inverter. The power loss simulator 802 can generate the inverter based on data, such as a technical data sheet, and can determine at least equivalent series resistance from the data sheet.

The power loss simulator 802 can use at least the resistive and switching power loss, the current, and the equivalent series resistance to determine a power loss across electrical components (e.g., device power loss) of the inverter. For example, the inverter can include at least one capacitor and at least one metal-oxide-semiconductor field-effect transistor (MOSFET). The power loss simulator 802 can determine the power loss across the at least one capacitor and the at least one MOSFET to determine an overall device power loss (e.g., dissipation, etc.). For example, after determining the power loss across the capacitor and the MOSFET, the power loss simulator 802 can determine the power loss across the inverter (e.g., electronic power loss) based on the power loss across the capacitor and the MOSFET. The power loss simulator 802 can determine the capacitor and MOSFET power loss using the SPICE parameters.

The system 800 can include at least one thermal simulator 804. The thermal simulator 804 can include at least one thermal simulation, and can receive the simulated power grid hardware from the power loss simulator 802. The thermal simulator 804 can determine a temperature (e.g., heat dissipation, etc.) of the electrical components (e.g., device temperature) of the power grid hardware during various operating conditions of the power grid hardware. For example, the power loss of the inverter can affect a temperature of the inverter which can affect an operating life span of the inverter. The thermal simulator 804 can input different operating conditions into the inverter and determine a temperature of the inverter at the different operating conditions. For example, the thermal simulator 804 can receive the power losses from the power loss simulator 802, simulate the power loss (e.g., voltage, conditions corresponding to the power loss, etc.) on the simulated inverter, and determine a temperature of various electrical components of the inverter. The thermal simulator 804 can determine a temperature of the inverter (e.g., electronic temperature) based on the temperature of the electrical components of the inverter.

The thermal simulator 804 can continuously adjust a load on the inverter and collect temperature measurements. Based on the load and the temperature measurements, the thermal simulator 804 can predict (e.g., extrapolate) a time and temperature failure point of the inverter. The thermal simulator 804 can use the power losses of at least one of the capacitor, the MOSFET, and the inverter to apply the load to the inverter and determine the temperature of at least one of the capacitor, the MOSFET, and the inverter.

The system 800 can include at least one life span calculator 806. The life span calculator 806 can receive at least the temperature from the thermal simulator 804. Using the temperature, the life span calculator 806 can determine a life span of the capacitor and the MOSFET. For example, based on the temperature of the capacitor, the life span calculator 806 can input the data into Equation (1):

$$L = {L}_{o} * {2}^{\frac{{T}_{o} - {T}_{op}}{10}} \qquad ( 1 )$$

where Tₒ is a reference temperature, Tₒₚ is an operating temperature of the inverter, Lₒ is an initial life span, and L is a predicted operating life span of the capacitor. In some implementations, the life span calculator 806 determines the operating life span based on the temperature, and the power loss is used to determine the temperature of the electrical components.

The life span calculator 806 can determine an operating life span of the MOSFET using at least the temperature of the MOSFET. The life span calculator 806 can receive the temperature of the MOSFET from the thermal simulator 804, and can input the temperature into:

$$MTTF = 8 E9 * {T}^{- 2.357} \qquad ( 2 )$$

where MTTF is mean time to failure of the MOSFET. Equation (2) can be derived from an interpolated MTTF vs temperature curve of the MOSFET, which can be determined based on material and electrical properties of the MOSFET.

The life span calculator 806 can determine an operating life span of the inverter based on the operating life spans of the MOSFET and the capacitor. For example, the life span calculator 806 can compare the operating life span of the MOSFET to the operating life span of the capacitor, and determine the operating life span of the inverter based on a shorter life span of the operating life span of the MOSFET and the operating life span of the capacitor. Consequently, the operating life span of the inverter can be a shortest operating life span of an electrical component of the inverter, indicating that the electrical components fails and thereby the inverter fails at the shortest operating life span.

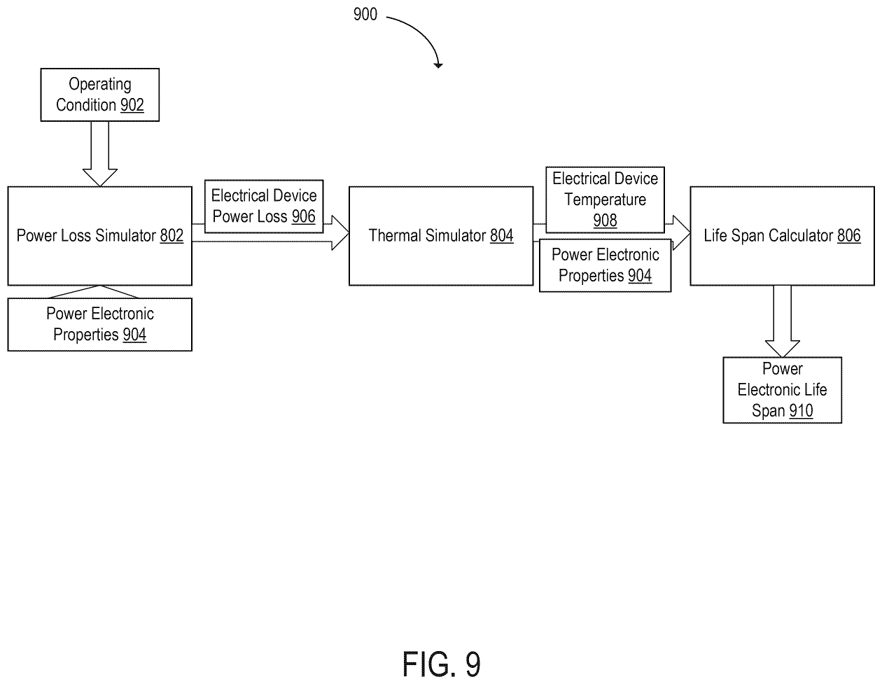

FIG. 9 is an example process 900 implemented by the system 800 to determine an operating life span of power grid hardware (e.g., power electronic, etc.). The power loss simulator 802 can receive or determine an operating condition 902. For example, the power loss simulator 802 can receive the direct current from the converter 316, and determine the operating condition, such as a voltage to operate the power electronic at, based on the direct current. In some implementations, the power loss simulator 802 determines the operating condition 902.

The power loss simulator 802 can generate a simulated power electronic such as an inverter which can include at least one electrical device, such as a MOSFET and a capacitor. The power loss simulator 802 can include power electronic properties 904 of the power electronic based on a datasheet corresponding to the simulated power electronic. The power loss simulator 802 can include at least one datasheet to generate the simulated power electronic based on, and the datasheet can include the power electronic properties 904, such as material and airflow properties, equivalent series resistance, etc. The power electronic properties 904 can include at least one of current, voltage, switching power loss, or resistive power loss determine based on, for example, a SPICE simulation of the power loss simulator 802.

Based on at least the power electronic properties 904, the power loss simulator 802 can determine at least one electrical device power loss 906 (e.g., device power loss). The electrical device power loss 906 can include at least one power loss of at least one electrical device, such as the MOSFET and the capacitor. The at least one electrical device power loss 906 can correspond to the operating condition 902 and a load (e.g., power consumption, etc.) on the power electronic based on the operating condition 902. For example, the electrical device power loss 906 can include a power loss value for each operating condition 902 input by the power loss simulator 802.

The power loss simulator 802 can provide the electrical device power loss 906 to the thermal simulator 804. Based on the electrical device power loss 906, the thermal simulator 804 can determine at least one electrical device temperature 908 (e.g., device temperature). For example, the thermal simulator 804 can simulate conditions corresponding to the electrical device power loss 906, and determine the electrical device temperature 908 resulting from the conditions. The conditions can include at least one of an operating condition, voltage, current, load on the power electronic, etc. corresponding to the electrical device power loss 906. For example, a higher load of the power electronic can correspond to a higher temperature and power loss of the electrical devices. The electrical device temperature 908 can include a range of temperature corresponding to the electrical device power loss 906.

The thermal simulator 804 can provide the electrical device temperature 908 to the life span calculator 806. The power loss simulator 802 can provide the power electronic properties 904 to the life span calculator 806. The power electronic properties 904 can include properties of the electrical devices, such as a life span of the electrical device indicated on the datasheet. The life span calculator 806 can determine an operating life span (e.g., service life, working life, etc.) of at least one electrical device based on the electrical device temperature 908 and the power electronic properties 904. For example, the life span calculator 806 can determine the operating life span of a capacitor based on an initial life span of the capacitor indicated by the power electronic properties 904 and the electrical device temperature 908.

Based on the operating life span of the electrical devices, the life span calculator 806 can determine a power electronic life span 910. The power electronic life span 910 can correspond to a shortest life span of the operating life spans of the electrical devices. In some implementations, the life span calculator 806 can output the power electronic life span 910 for each of the operating conditions 902. For example, the electrical device power loss 906, the electrical device temperature 908, and the power electronic life span 910 can correspond to the operating condition 902.

In some implementations, the power electronic life span 910 can be used to determine or adjust the failure and aging model. For example, an end point of the failure and aging model can correspond to the power electronic life span 910. The failure and aging model can be adjusted using the power electronic life span 910, such as a slope or the end point.

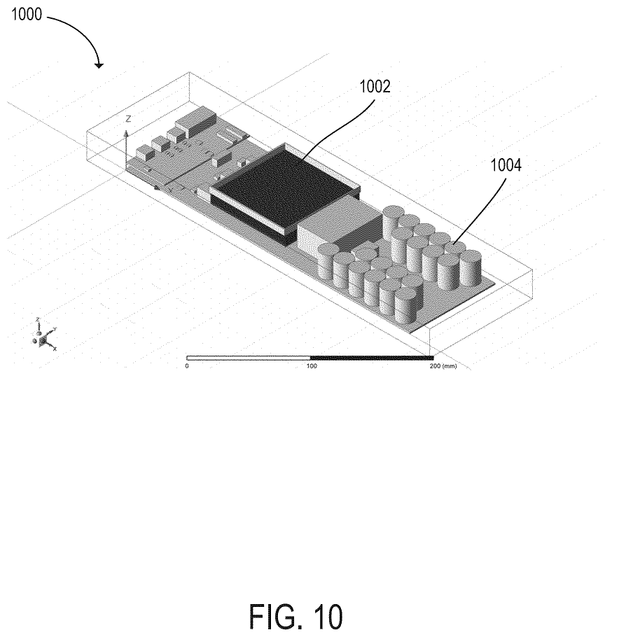

FIG. 10 depicts an example of the simulated power electronic 1000. The simulated power electronic 1000 can be an inverter and can include electrical devices. The electrical devices can include a MOSFET 1002, and at least one capacitor 1004. The simulated power electronic 1000 can include any number of MOSFETs 1002 and capacitors 1004 as well as other electrical devices.

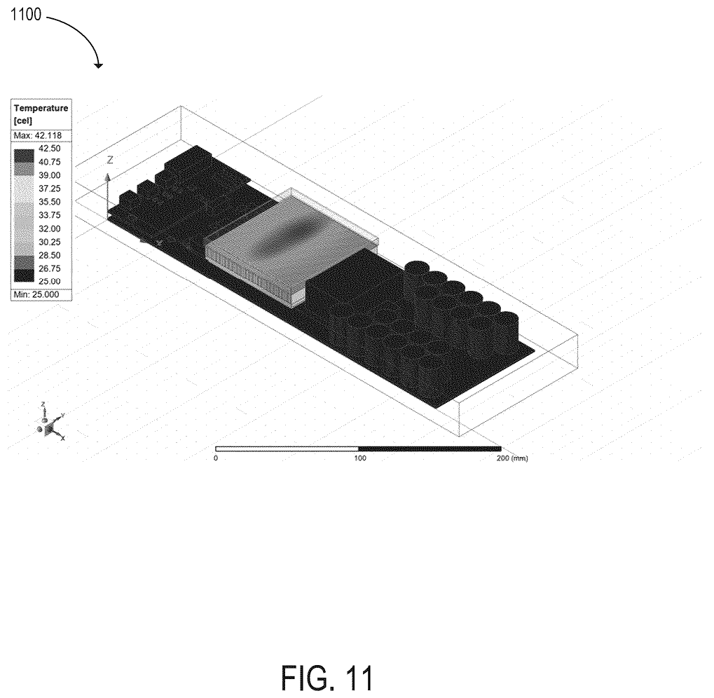

FIG. 11 depicts an example temperature map 1100 resulting from the thermal simulator 804 simulating the electrical device power loss 906 on the simulated power electronic 1000. As shown in FIG. 11, a temperature of the MOSFET 1002 can be greater than a temperature of the capacitor 1004.

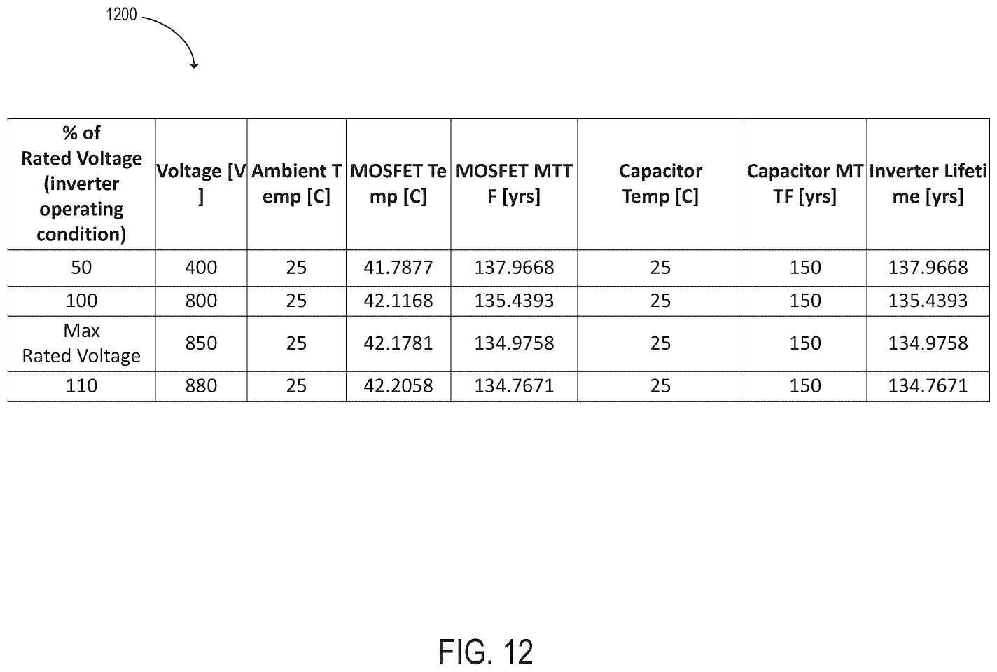

FIG. 12 is an example table 1200 of results of the power loss simulator 802, the thermal simulator 804, and the life span calculator 806. The table 1200 can include operating conditions 902 corresponding to a voltage of the simulated power grid hardware and an ambient temperature. The operating condition 902 can determine a voltage the power grid hardware uses (e.g., runs at, etc.) The MOSFET temperature and the capacitor temperature can be determined by the thermal simulator 804, and can correspond to the operating condition 902. The MOSFET MTTF and capacitor MTTF in years can be determined by the life span calculator 806 and can correspond to the operating condition 902. The life span calculator 806 can determine the power grid hardware life span (e.g., the inverter life span), based on a shorter of the MOSFET MTTF and the capacitor MTTF which, as shown in table 1200, can be the MOSFET MTTF. Consequently, the inverter life span can be equal to the MOSFET MTTF in some implementations.

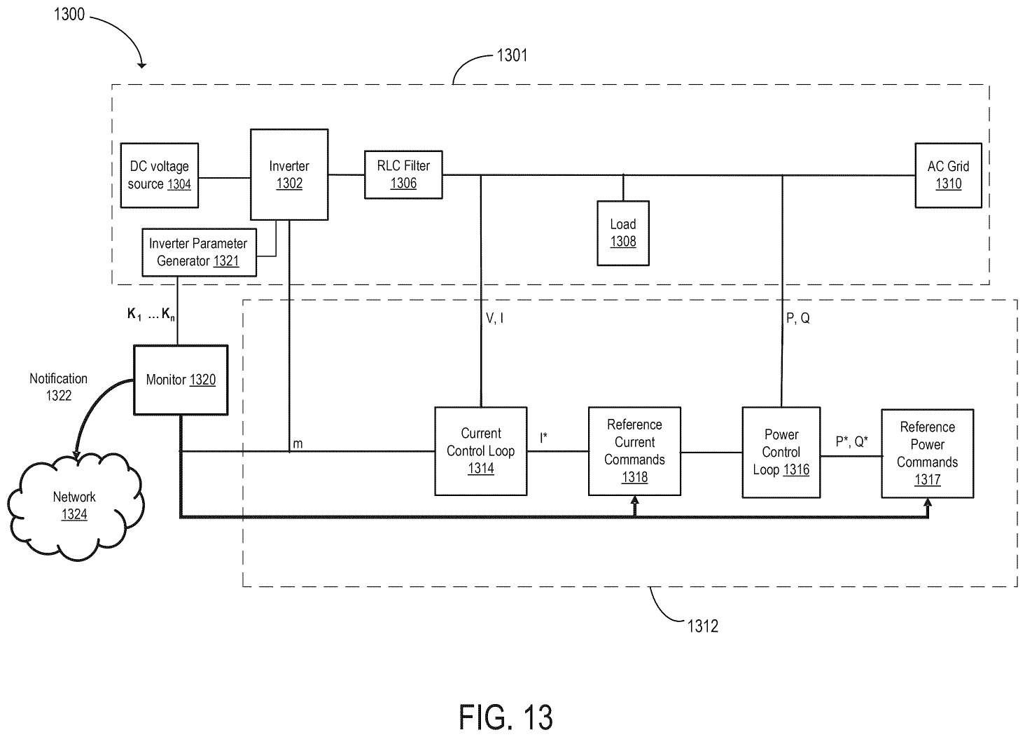

FIG. 13 depicts an example system 1300 of controlling a power grid hardware, such as an inverter 1302. The inverter 1302 can be included in an electrical system 1301 of the system 1300. The inverter 1302 can be electrically coupled to a direct current (DC) voltage source 1304, which, in some implementations, can be the converter 316. The system 1300 can be a hardware or software system. The inverter 1302 can receive direct current from the DC voltage source 1304, and convert the direct current into alternating current (AC). The AC can pass through a resistor, inductor, capacitor (RLC) filter 1306 which can filter a portion of the AC. From the RLC filter 1306, the AC can be received by a load 1308 and an AC grid 1310. The load 1308 can consume power and can be connected to, for example, an electrical device. The AC grid 1310 can store and supply the AC. For example, the AC grid 1310 can receive excess AC not consumed by the load 1308, and provide AC to the load 1308 in response to input from the inverter 1302 being insufficient.

The inverter 1302 can include at least one switching element, such as a MOSFET, an insulator gate bipolar transistor (IGBT), or another switching element. The inverter 1302 can include the MOSFET 1002 and the capacitor 1004. The switching element can include gates, and the gates can be controlled by a control system 1312. To control the gates, the control system 1312 can receive reference signals from the electrical system 1301. The reference signals can include at least one of voltage, current, or power. The reference signals can determine output targets of the inverter 1302. For example, the control system 1312 can use the reference signals as a target such that an output of the inverter 1302 is equal to the reference signals. The electrical system 1301 can provide a voltage (V) and a current (I) of the electrical system 1301 to a current control loop 1314 of the control system 1312. Based on the voltage and the current, the current control loop 1314 can generate pulse-width modulation (PWM) gate signals (m) for the switching elements of the inverter 1302. The PWM gate signals can, for example, control an output of the inverter 1302, such as an amount of current generated by the inverter 1302. The PWM gate signals can be generated based on the reference current commands 1318 and the reference power commands 1317. In various implementations, the reference current commands 1318 and the reference power commands 1317 are an external reference, such as stored in a database. The reference power commands 1317 and the reference current commands 1318 can correlate to a model or make of the inverter 1302. The PWM gate signals can adjust the operating condition of the inverter.

The electrical system 1301 can provide a power including an active power (P) and a reactive power (Q) of the electrical system 1301 to a power control loop 1316 of the control system 1312. Using the power, the power control loop 1316 can generate at least one reference current (I*) command 1318 for the current control loop 1314. The current control loop 1314 can generate the PWM gate signals based on at least one of the voltage, the current, or the reference current. The power control loop 1316 can generate reference active power (P*) and reference reactive power (Q*) to generate reference power commands 1317. The reference power commands 1317 and the reference current commands 1318 can be combined to generate the PWM gate signals to control the inverter 1302.

The system 1300 can include at least one monitor 1320. The monitor 1320 can receive inverter parameters K₁ . . . Kₙ (e.g., harmonic coefficients, gain constants, etc.) from the inverter 1302. The inverter parameters can be generated, determined, or otherwise derived by the system 800 while determining, for example, the power electronic life span 910 of the inverter 1302. The system 800 can determine which parameters of the inverter switching elements (e.g., MOSFET, etc.) are lifetime information signals or can be used to derive a lifetime-dependent signal. For example, the system 800 can determine which of the inverter parameters the power electronic life span 910 is at least partially dependent on. The system 800 can transmit the inverter parameters to the monitor 1320 to control the control system 1312.

In various implementations, the system 1300 can include an inverter parameter generator 1321. The inverter parameter generator 1321 can be communicatively coupled to the inverter 1302 and the monitor 1320. In various implementations, the inverter parameter generator 1321 includes or executes the system 800, and can determine the inverter parameters. In various implementations, the inverter parameters can be determined by at least the make and model of the inverter 1302. The inverter parameter generator 1321 can determine the inverter parameters related to the power electronic life span 910 of the inverter 1302 based on at least signals provided by the inverter 1302. The inverter parameter generator 1321 can transmit the inverter parameters to the monitor 1320, and the monitor 1320 can use the inverter parameters to adjust the control system 1312 to adjust the output of the inverter 1302 accordingly. In other implementations, the system 1300 may not include the inverter parameter generator 1321.

The inverter parameters can indicate an output or characteristics of the output of the inverter 1302. The inverter parameters can include empirical or design constants, harmonic coefficients in Fourier Series terms, proportional gains, etc. The inverter parameters can be inverter switching lifetime parameters. Based on the inverter parameters, the monitor 1320 can alter a behavior of the inverter 1302, such as the operating condition, by determining age corresponding to a life span of the inverter 1302. For example, the monitor 1320 can determine a power electronic age based on the inverter parameters.

Based on at least one of the power electronic age or the inverter parameters, the monitor 1320 can reduce an output of the inverter 1302 (e.g., current, etc.), disable the inverter 1302 in cases of failure, and generate a notification 1322 to an operator. The monitor 1320 can be communicatively coupled to a network 1324, and the monitor 1320 can transmit the notification 1322 to the operator via the network 1324. The monitor 1320 can compare the power electronic age to one or more thresholds. The one or more thresholds can correspond to, for example, the power electronic life span 910. For example, the monitor 1320 can, in response to determining that the power electronic age is greater than or equal to a first threshold and less than or equal to a second threshold, reduce the output of the inverter 1302. To reduce the output the monitor 1320 can, for example, adjust at least one of the reference current commands 1318 or the reference power commands 1317 to reduce at least one of a voltage, current, reactive power, or active power of the inverter 1302. The first threshold can be, for example, a first percentage of the power electronic life span 910 and the second threshold can be a second percentage of the power electronic life span 910, the second percentage greater than the first percentage. For example, the first threshold can be 70% of the power electronic life span 910 and the second threshold can be 90% of the power electronic life span 910.

The monitor 1320 can, in response to determining that at least one of the inverter parameters is greater than an upper parameter threshold or less than a lower parameter threshold, disable the inverter 1302. For example, the monitor 1320 can disable the inverter 1302 upon determining that the inverter parameters indicate a voltage of 0V. The monitor 1320 can, in response to determining that the power electronic age is greater than a second threshold, generate the notification 1322. The notification 1322 can indicate to the operator that the power electronic age of the inverter 1302 is reaching or has reached the power electronic life span 910, and indicates that the inverter 1302 should be replaced, services, or checked (e.g., maintained, etc.)

In some implementations, the monitor 1320 may not be coupled to the control system 1312. The monitor 1320 can act as a secondary control system of the electrical system 1301.

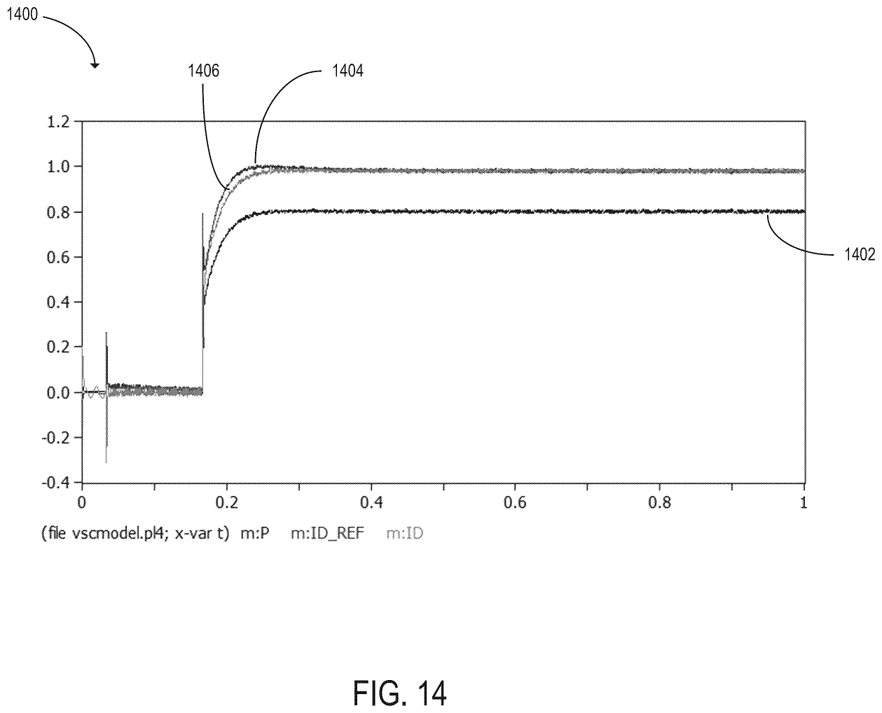

FIG. 14 depicts a graph 1400 of an example of the inverter 1302. The inverter 1302 can be turned off initially, then commanded to 80% rated power (e.g., 80% rated voltage) at 0.16 second, as shown in the graph 1400. Units shown in the graph 1400 can be in per-unit quantities as a ratio against a base value. A first line 1402 of the graph 1400 can be an output power of the inverter 1302, a second line 1404 can be a commanded reference current, and a third line 1406 can be a measured output current. The graph 1400 can demonstrate regulation of the inverter 1302 by the control system 1312. For example, the first line 1402 can correspond to the power signal provided to the power control loop 1316, the second line 1404 can correspond to the reference current commands 1318, and the third line 1406 can correspond to the current signal provided to the current control loop 1314.

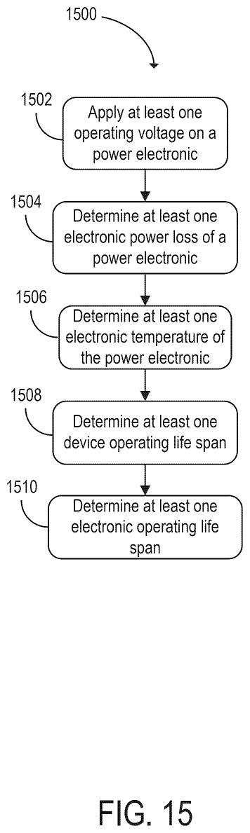

FIG. 15 is a flow diagram of an example method 1500 for determining an electronic operating life span (e.g., power electronic life span 910). The method 1500 can be performed using various systems described herein. Various steps in the method 1500 may be repeated, omitted, performed in various orders, or otherwise modified. Various steps in the method 1500 may be run concurrently, in parallel, or individually.

The method 1500, at block 1502, can include applying at least one operating voltage on a power electronic (e.g., inverter 1302) including at least one electrical device (e.g., MOSFET 1002, capacitor 1004). The at least one electrical device can include a capacitor and a MOSFET and the power electronic can include an inverter. The at least one operating voltage can correspond to power grid dynamics. For example, the power grid dynamics can be based on historical power grid dynamic data, and the operating voltage can be determined based on the power grid dynamics.

The method 1500, at block 1504, can include determining at least one electronic power loss of the power electronic corresponding to the at least one operating voltage based on at least one device power loss of the at least one electrical device. The at least one device power loss can be determined using parameters determined by electrical simulations. The electrical simulation can include SPICE simulations. The parameters can include at least one of current, voltage, resistive power loss, and switching power loss

The method 1500, at block 1506, can include determining at least one electronic temperature of the power electronic based on at least one device temperature of the at least one electrical device and the at least one device power loss. The device temperature can be determined by applying conditions corresponding to the device power loss to the electrical device, and determining, collecting, or otherwise measuring the temperature of the electrical device caused by (e.g., as a result of, etc.) the device power loss. The electronic temperature can be determined based on the at least one device temperatures, such as a combination or average of the device temperatures.

The method 1500, at block 1508, can include determining at least one device operating life span of the at least one electrical device based on the at least one device temperature. The device operating life span can be determined per electrical device using the device temperature, such as by one or more curves or equations. The device operating life span can be determined based on parameters or properties of the electrical device, such as resistance or material properties determined from a technical datasheet of the electrical device.

The method 1500, at block 1510, can include determining an electronic operating life span of the power electronic based on the at least one device operating life span. The electronic operating life span can correspond to a shortest of the at least one device operating life spans. For example, the electronic operating life span can be equal to the shortest life span of the device operating life spans.

In various implementations, the method 1500 can include receiving parameters of the power electronic indicating an output of the power electronic. The parameters can be inverter parameters, and can indicate, for example, at least one of an AC output of the inverter. The method 1500 can include determining a power electronic age based on the parameters. For example, the method 1500 can include comparing the parameter to a chart or a table, and determining the power electronic age corresponding to the parameter. The method 1500 can include in response to determining that the power electronic age is greater than or equal to a first threshold and less than or equal to a second threshold, adjusting the output of the power electronic. The output can be adjusted by adjusting parameters of a control loop of the inverter. The first threshold and the second threshold can be determined based on the electronic operating life span

In various implementations, the method 1500 can include in response to determining that the power electronic age is greater than the second threshold, generating a notification to an operator. The power electronic age being greater than the second threshold can indicate that the power electronic should be replaced or checked by the operator.

### Definitions.

No claim element herein is to be construed under the provisions of 35 U.S.C. § 112(f), unless the element is expressly recited using the phrase “means for.”

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various implementations, are intended to indicate that such implementations are possible examples, representations, or illustrations of possible implementations (and such terms are not intended to connote that such implementations are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

The term “or,” as used herein, is used in its inclusive sense (and not in its exclusive sense) so that when used to connect a list of elements, the term “or” means one, some, or all of the elements in the list. Conjunctive language such as the phrase “at least one of X, Y, and Z,” unless specifically stated otherwise, is understood to convey that an element may be either X, Y, Z; X and Y; X and Z; Y and Z; or X, Y, and Z (i.e., any combination of X, Y, and Z). Thus, such conjunctive language is not generally intended to imply that certain implementations require at least one of X, at least one of Y, and at least one of Z to each be present, unless otherwise indicated.

References herein to the positions of elements (e.g., “top,” “bottom,” “above,” “below”) are merely used to describe the orientation of various elements in the FIGURES. It should be noted that the orientation of various elements may differ according to other exemplary implementations, and that such variations are intended to be encompassed by the present disclosure.

Although the figures and description may illustrate a specific order of method steps, the order of such steps may differ from what is depicted and described, unless specified differently above. Also, two or more steps may be performed concurrently or with partial concurrence, unless specified differently above.

What is claimed is:

1. A method, comprising:
extracting, by one or more processors, parameters from power grid dynamics data to perform power grid simulation testing;
sending, by the one or more processors, a reference to a power grid device based on the parameters;
generating, by the one or more processors, stress information based on the reference sent via the power grid device to a power grid hardware;
collecting, by the one or more processors, a response from the power grid hardware to the stress information;
identifying, by the one or more processors, behaviors of the response; and
extracting, by the one or more processors, a failure and aging model of the power grid hardware.

2. The method of claim 1, wherein the stress information comprises voltage, current, and temperature signals.

3. The method of claim 1, wherein the power grid hardware is a wide bandgap power electronic.

4. The method of claim 1, wherein the power grid device is a power amplifier.

5. The method of claim 1, wherein the response comprises drain-source voltage (Vds), gate-source voltage (Vgs), gate-source current (Igs), and drain-source current (Ids) data.

6. The method of claim 1, wherein collecting the response further comprises collecting the response over a plurality of time points for the response.

7. The method of claim 1, wherein the power grid dynamics data is at least one of historic power grid dynamics data or real-time power grid dynamics data.

8. The method of claim 1, wherein the reference comprises voltage, current, and temperature parameters.

9. A system, comprising:
one or more processors to:
extract parameters from power grid dynamics data;
send a reference, based on the parameters, to a power grid device;
generate stress information based on the reference via the power grid device to a power grid hardware;
collect a response from the power grid hardware to the stress information;
identify behaviors of the response; and
extract a failure and aging model of the power grid hardware.

10. The system of claim 9, wherein the stress information comprises voltage, current, and temperature signals.

11. The system of claim 9, wherein the power grid hardware is a wide bandgap power electronic.

12. The system of claim 9, wherein the power grid device is a power amplifier.

13. The system of claim 9, wherein the response comprises drain-source voltage (Vds), gate-source voltage (Vgs), gate-source current (Igs), and drain-source current (Ids) data.

14. The system of claim 9, wherein collecting the response further comprises collecting the response over a plurality of time points for the response.

15. The system of claim 9, wherein the power grid dynamics data is at least one of historic power grid dynamics data or real-time power grid dynamics data.

16. The system of claim 9, wherein the reference comprises voltage, current, and temperature parameters.

17. A method, comprising:
applying, by one or more processors, at least one operating voltage on a power electronic comprising at least one electrical device;
determining, by the one or more processors, at least one electronic power loss of the power electronic corresponding to the at least one operating voltage based on at least one device power loss of the at least one electrical device;
determining, by the one or more processors, at least one electronic temperature of the power electronic based on at least one device temperature of the at least one electrical device and the at least one device power loss;
determining, by the one or more processors, at least one device operating life span of the at least one electrical device based on the at least one device temperature; and
determining, by the one or more processors, an electronic operating life span of the power electronic based on the at least one device operating life span.

18. The method of claim 17, wherein the at least one electrical device comprises a capacitor and a metal-oxide-semiconductor field-effect transistor (MOSFET) and the power electronic comprises an inverter, the at least one operating voltage corresponding to power grid dynamics.

19. The method of claim 17, wherein the at least one device power loss is determined using parameters determined by electrical simulations, the parameters comprising at least one of current, voltage, resistive power loss, and switching power loss.

20. The method of claim 17, further comprising:
receiving, by the one or more processors, parameters of the power electronic indicating an output of the power electronic;
determining, by the one or more processors, a power electronic age based on the parameters;
in response to determining that the power electronic age is greater than or equal to a first threshold and less than or equal to a second threshold, adjusting, by the one or more processors, the output of the power electronic; and
in response to determining that the power electronic age is greater than the second threshold, generating, by the one or more processors a notification to an operator;
wherein the first threshold and the second threshold are determined based on the electronic operating life span.
